(19) United States
(12) Patent Application Publication
(10) Pub. No.: US 2021/0181627 A1
(43) Pub. Date: Jun. 17, 2021

(54) PATTERN-FORMING METHOD AND RADIATION-SENSITIVE COMPOSITION

(71) Applicants: JSR CORPORATION, Tokyo (JP); CORNELL UNIVERSITY, Ithaca, NY (US)

(72) Inventors: Kazunori SAKAI, Tokyo (JP); Vasiliki KOSMA, Leuven (BE); Christopher K. OBER, Ithaca, NY (US); Emmanuel P. GIANNELIS, Ithaca, NY (US)

(73) Assignees: JSR CORPORATION, Tokyo (JP); CORNELL UNIVERSITY, Ithaca, NY (US)

(21) Appl. No.: 17/176,263

(22) Filed: Feb. 16, 2021

Related U.S. Application Data
(63) Continuation of application No. PCT/JP2019/032292, filed on Aug. 19, 2019.
(60) Provisional application No. 62/764,983, filed on Aug. 20, 2018.

(51) Int. Cl. G03F 7/004; G03F 7/20; C07F 3/06; C07F 7/00; C07F 15/06

(52) U.S. Cl. CPC G03F 7/0042; G03F 7/2004; C07F 15/06; C07F 3/06; C07F 7/00; G03F 7/0045

(57) ABSTRACT

A pattern-forming method includes: applying directly or indirectly on a substrate a radiation-sensitive composition containing a complex and an organic solvent to form a film; exposing the film to an ultraviolet ray, a far ultraviolet ray, an extreme ultraviolet ray, or an electron beam; and developing the film exposed, wherein the complex is represented by formula (1).

[MₘLₙQₚ] (1)

In the formula (1), M represents a zinc atom, a cobalt atom, a nickel atom, a hafnium atom, a zirconium atom, a titanium atom, an iron atom, a chromium atom, a manganese atom, or an indium atom; and L represents a ligand derived from a compound represented by formula (2).

R¹—CHR³—R² (2)

In the formula (2), R¹ and R² each independently represent —C(═O)—R^{A}, —C(═O)—OR^{B}, or —CN.

### CROSS-REFERENCE TO RELATED APPLICATIONS

The present application is a continuation application of International Application No. PCT/JP2019/032292, filed Aug. 19, 2019, which claims priority to U.S. Patent Application No. 62/764,983, filed Aug. 20, 2018. The contents of these applications are incorporated herein by reference in their entirety.

### BACKGROUND OF THE INVENTION

### Field of the Invention

The present invention relates to a pattern-forming method and a radiation-sensitive composition.

### Description of the Related Art

A general radiation-sensitive composition for use in microfabrication by lithography generates an acid at a light-exposed region upon exposure to, e.g., an electromagnetic wave such as an ultraviolet ray, a far ultraviolet ray (for example, an ArF excimer laser beam, a KrF excimer laser beam, etc.) or an extreme ultraviolet ray, or a charged particle ray such as an electron beam. A chemical reaction in which the acid serves as a catalyst causes a difference in rates of dissolution in a developer solution between light-exposed regions and light-unexposed regions, whereby a pattern is formed on a substrate. The pattern thus formed can be used as a mask or the like in substrate processing.

Such radiation-sensitive compositions are required to have improved resist performance along with miniaturization in processing techniques. To meet this requirement, types, molecular structures, and the like of polymers, acid generating agents, and other components which may be used in radiation-sensitive compositions have been investigated, and combinations thereof have been further investigated in detail (see Japanese Unexamined Patent Application, Publication Nos. H11-125907, H8-146610, and 2000-298347).

Furthermore, improving sensitivity to, in particular, an extreme ultraviolet ray or an electron beam has been required recently. To meet this requirement, use, as a component of the radiation-sensitive composition, of a particle having a metal oxide as a principal component has been investigated. It is considered that such a particle generates secondary electrons through absorption of extreme ultraviolet rays or the like, and that the generation of an acid from an acid generating agent or the like is promoted by an action of the secondary electrons, thereby enabling the sensitivity to be improved.

### SUMMARY OF THE INVENTION

According to an aspect of the present invention, a pattern-forming method includes: applying directly or indirectly on a substrate a radiation-sensitive composition containing a complex and an organic solvent to form a film; exposing the film to an ultraviolet ray, a far ultraviolet ray, an extreme ultraviolet ray, or an electron beam; and developing the film exposed, wherein the complex is represented by formula (1).

[MₘLₙQₚ] (1)

In the formula (1), M represents a zinc atom, a cobalt atom, a nickel atom, a hafnium atom, a zirconium atom, a titanium atom, an iron atom, a chromium atom, a manganese atom, or an indium atom; m is a number of atoms represented by M in the complex represented by the formula (1) and is an integer of 1 to 20, wherein in a case in which m is no less than 2, a plurality of Ms are identical or different; L represents a ligand derived from a compound represented by formula (2); n is a number of ligands represented by L in the complex represented by the formula (1) and is an integer of 1 to 80, wherein in a case in which n is no less than 2, a plurality of Ls are identical or different; Q represents a ligand not falling under a definition of L; and p is a number of ligands represented by Q in the complex represented by the formula (1) and is an integer of 0 to 40, wherein in a case in which p is no less than 2, a plurality of Qs are identical or different.

R¹—CHR³—R² (2)

In the formula (2), R¹ and R² each independently represent —C(═O)—R^{A}, —C(═O)—OR^{B}, or —CN, wherein R^{A} and R^{B} each independently represent an aryl group having 6 to 20 carbon atoms or a fluorine atom-substituted or unsubstituted alkyl group having 1 to 20 carbon atoms; and R³ represents a hydrogen atom or a monovalent hydrocarbon group having 1 to 20 carbon atoms.

According to another aspect of the present invention, a radiation-sensitive composition contains a complex and an organic solvent, wherein the complex is represented by the formula (1).

### DESCRIPTION OF THE EMBODIMENTS

Even a pattern-forming method which uses a radiation-sensitive composition containing the aforementioned particle fails to attain a sufficient level of resolution and sensitivity.

According to one embodiment of the present invention, a pattern-forming method includes:

applying directly or indirectly on a substrate a radiation-sensitive composition containing a complex and an organic solvent to form a film;

exposing the film to an ultraviolet ray, a far ultraviolet ray, an extreme ultraviolet ray, or an electron beam; and

developing the film exposed,

wherein the complex is represented by the following formula (1):

[MₘLₙQₚ] (1)

wherein, in the above formula (1),

M represents a zinc atom, a cobalt atom, a nickel atom, a hafnium atom, a zirconium atom, a titanium atom, an iron atom, a chromium atom, a manganese atom, or an indium atom;

m is the number of atoms represented by M in the complex represented by the formula (1) and is an integer of 1 to 20, wherein in a case in which m is no less than 2, a plurality of Ms are identical or different;

L represents a ligand derived from a compound represented by the following formula (2):

R¹—CHR³—R² (2)
wherein, in the above formula (2),
R¹ and R² each independently represent —C(═O)—R^{A}, —C(═O)—OR^{B}, or —CN, wherein R^{A} and R^{B} each independently represent an aryl group having 6 to 20 carbon atoms or a fluorine atom-substituted or unsubstituted alkyl group having 1 to 20 carbon atoms; and
R³ represents a hydrogen atom or a monovalent hydrocarbon group having 1 to 20 carbon atoms,

n is the number of ligands represented by L in the complex represented by the formula (1) and is an integer of 1 to 80, wherein in a case in which n is no less than 2, a plurality of Ls are identical or different;

Q represents a ligand not falling under a definition of L; and

p is the number of ligands represented by Q in the complex represented by the formula (1) and is an integer of 0 to 40, wherein in a case in which p is no less than 2, a plurality of Qs are identical or different.

According to another embodiment of the present invention, a radiation-sensitive composition contains a complex and an organic solvent, wherein the complex is represented by the above formula (1).

The pattern-forming method and the radiation-sensitive composition of the embodiments of the present invention enable formation of a pattern with high resolution in a highly sensitive manner. Therefore, these can be suitably used for formation of fine patterns in lithography processes of various types of electronic devices such as semiconductor devices and liquid crystal devices, for which microfabrication is expected to progress further hereafter.

### Pattern-Forming Method

The pattern-forming method according to the one embodiment of the present invention includes: a step of applying directly or indirectly on a substrate a radiation-sensitive composition (hereinafter, may be also referred to as “(X) radiation-sensitive composition” or “radiation-sensitive composition (X)”) containing a complex (hereinafter, may be also referred to as “(A) complex” or “complex (A)”) and an organic solvent (hereinafter, may be also referred to as “(B) organic solvent” or “organic solvent (B)”) to form a film (hereinafter, may be also referred to as “applying step”); a step of exposing the film to an ultraviolet ray, a far ultraviolet ray, an extreme ultraviolet ray, or an electron beam (hereinafter, may be also referred to as “exposing step”); and a step of developing the film exposed (hereinafter, may be also referred to as “developing step”), wherein the complex is represented by the above formula (1).

The pattern-forming method of the one embodiment of the present invention enables formation of a pattern with high resolution in a highly sensitive manner. Hereinafter, each step will be described.

Applying Step

In this step, the radiation-sensitive composition (X) is applied directly or indirectly on a substrate. Accordingly, a film is formed. The radiation-sensitive composition (X) will be described below.

Radiation-Sensitive Composition

The radiation-sensitive composition (X) contains the complex (A) and the organic solvent (B). The radiation-sensitive composition (X) preferably also contains a radiation-sensitive acid generating agent (hereinafter, may be also referred to as “(C) acid generating agent” or “acid generating agent (C)”), and may also contain, within a range not leading to impairment of the effects of the present invention, other component(s).

Due to the pattern-forming composition including each of the steps and involving the radiation-sensitive composition (X), which contains the complex (A) and the organic compound (B), both of the resolution and the sensitivity are superior. Although not necessarily clarified and without wishing to be bound by any theory, the reason for achieving the aforementioned effects due to the radiation-sensitive composition (X) involving such a constitution may be presumed, for example, as in the following. It is considered that due to the radiation-sensitive composition (X) forming a pattern by using the complex (A), which is comparatively small in size, improvement of the resolution is enabled. Furthermore, it is considered that the complex (A) deteriorates with comparatively low energy and alters solubility in a developer solution, and that as a result, improvement of the sensitivity of the radiation-sensitive composition (X) is enabled. Hereinafter, each component will be described.

(A) Complex

The complex (A) is a complex represented by the following formula (1).

[MₘLₙQₚ] (1)

In the above formula (1),

M represents a zinc atom, a cobalt atom, a nickel atom, a hafnium atom, a zirconium atom, a titanium atom, an iron atom, a chromium atom, a manganese atom, or an indium atom;

m is the number of atoms represented by M in the complex represented by the formula (1) and is an integer of 1 to 20, wherein in a case in which m is no less than 2, a plurality of Ms are identical or different;

L represents a ligand derived from a compound represented by the following formula (2);

n is the number of ligands represented by L in the complex represented by the formula (1) and is an integer of 1 to 80, wherein in a case in which n is no less than 2, a plurality of Ls are identical or different;

Q represents a ligand not falling under a definition of L; and

p is the number of ligands represented by Q in the complex represented by the formula (1) and is an integer of 0 to 40, wherein in a case in which p is no less than 2, a plurality of Qs are identical or different.

R¹—CHR³—R² (2)

In the above formula (2),

R¹ and R² each independently represent —C(═O)—R^{A}, —C(═O)—OR^{B}, or —CN, wherein R^{A} and R^{B} each independently represent an aryl group having 6 to 20 carbon atoms or a fluorine atom-substituted or unsubstituted alkyl group having 1 to 20 carbon atoms; and

R³ represents a hydrogen atom or a monovalent hydrocarbon group having 1 to 20 carbon atoms.

M represents preferably a zinc atom, a cobalt atom, or a hafnium atom. When M represents one of the above metal atoms, the resolution and the sensitivity can be further improved.

m is preferably 1 to 10, more preferably 1 to 3, still more preferably 1 or 2, and particularly preferably 1. When m falls within the above range, the resolution and the sensitivity can be further improved.

With regard to the compound represented by the formula (2) (hereinafter, may be also referred to as “compound (2)”) which gives L, the aryl group having 6 to 20 carbon atoms which may be represented by R^{A} or R^{B} in —C(═O)—R^{A} or —C(═O)—OR^{B}, respectively, which may be represented by R¹ and/or R², is exemplified by a phenyl group, a tolyl group, a xylyl group, a mesityl group, a naphthyl group, an anthryl group, a phenanthryl group, a tetracenyl group, a pyrenyl group, and the like.

The unsubstituted alkyl group having 1 to 20 carbon atoms which may be represented by R^{A} and/or R^{B} is exemplified by a methyl group, an ethyl group, an n-propyl group, an i-propyl group, an n-butyl group, an i-butyl group, a sec-butyl group, a t-butyl group, and the like.

The fluorine atom-substituted alkyl group having 1 to 20 carbon atoms which may be represented by R^{A} and/or R^{B} is exemplified by a group obtained by substituting with a fluorine atom, a part or all of hydrogen atoms included in the unsubstituted alkyl group having 1 to 20 carbon atoms exemplified above as R^{A} and/or R^{B}, and the like.

Each of R^{A} and R^{B} represents preferably the fluorine atom-substituted or unsubstituted alkyl group; more preferably a fluorine atom-substituted or unsubstituted alkyl group having 1 to 4 carbon atoms; still more preferably a fluorine atom-substituted or unsubstituted methyl group or an unsubstituted ethyl group, propyl group, or butyl group; and particularly preferably a methyl group, an ethyl group, a t-butyl group, or a trifluoromethyl group. When each of R^{A} and R^{B} is set to be one of the above groups, the resolution and the sensitivity can be further improved.

Each of R¹ and R² represents preferably —C(═O)—R^{A} or —C(═O)—OR^{B}, and more preferably —C(═O)—OR^{B}. When each of R¹ and R² is set to be one of the above groups, the resolution and the sensitivity can be further improved.

The monovalent hydrocarbon group having 1 to 20 atoms which may be represented by R³ is exemplified by a chain hydrocarbon group having 1 to 20 carbon atoms, such as an alkyl group, an alkenyl group, or an alkynyl group; a monocyclic or polycylic alicyclic hydrocarbon group having 3 to 20 carbon atoms; an aromatic hydrocarbon group having 6 to 20 atoms, such as an aryl group or an aralkyl group; and the like.

R³ represents preferably a hydrogen atom.

Examples of the compound (2) include compounds represented by the following formulae (2-1) to (2-15) (hereinafter, may be also referred to as “compounds (2-1) to (2-15)”), and the like.

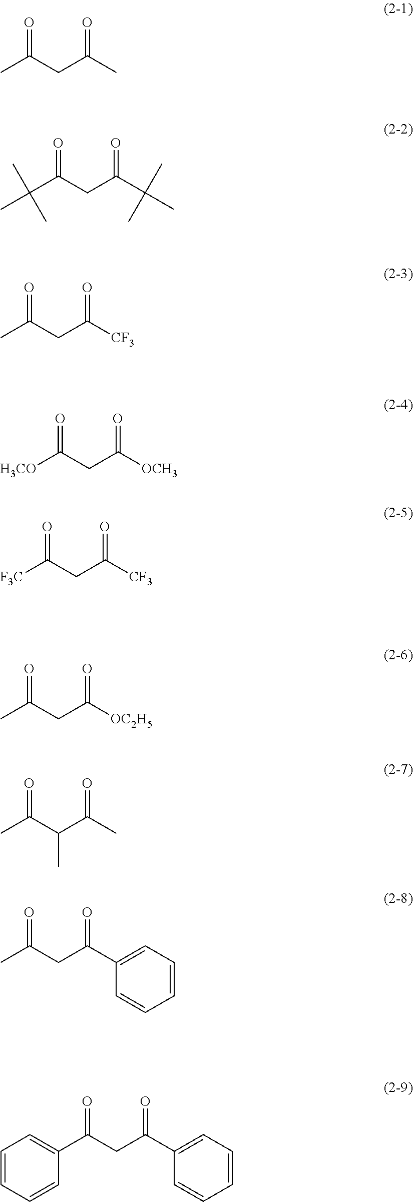

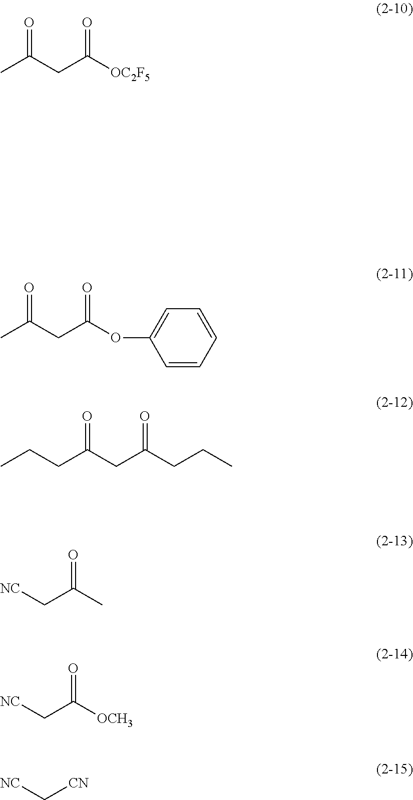

Of these, the compound (2-1), (2-2), (2-3), (2-4), or (2-6) is preferred.

In the above formula (1), n is preferably 1 to 40, more preferably 1 to 12, still more preferably 1 to 8, and particularly preferably 2 to 4.

The ligand not falling under a definition of L which is represented by Q is exemplified by:

monodentate ligands such as a hydroxo ligand, a carboxy ligand, an amido ligand, and an ammonia ligand;

polydentate ligands derived from a hydroxy acid ester, a hydrocarbon having a π bond, or a diphosphine; and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like.

Examples of the hydroxy acid ester include glycolic acid esters, lactic acid esters, 2-hydroxycyclohexane-1-carboxylic acid esters, salicylic acid esters, and the like.

Examples of the hydrocarbon having a π bond include:

chain olefins such as ethylene and propylene;

cyclic olefins such as cyclopentene, cyclohexene, and norbornene;

chain dienes such as butadiene and isoprene;

cyclic dienes such as cyclopentadiene, methylcyclopentadiene, pentamethylcyclopentadiene, cyclohexadiene, and norbornadiene;

aromatic hydrocarbons such as benzene, toluene, xylene, hexamethylbenzene, naphthalene, and indene; and the like.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

In the above formula (1), p is preferably 0 to 20, more preferably 0 to 10, still more preferably 0 to 3, and particularly preferably 0.

The complex (A) is exemplified by complexes represented by the following formulae (A1) to (A15) (hereinafter, may be also referred to as complexes (A1) to (A15)), and the like.

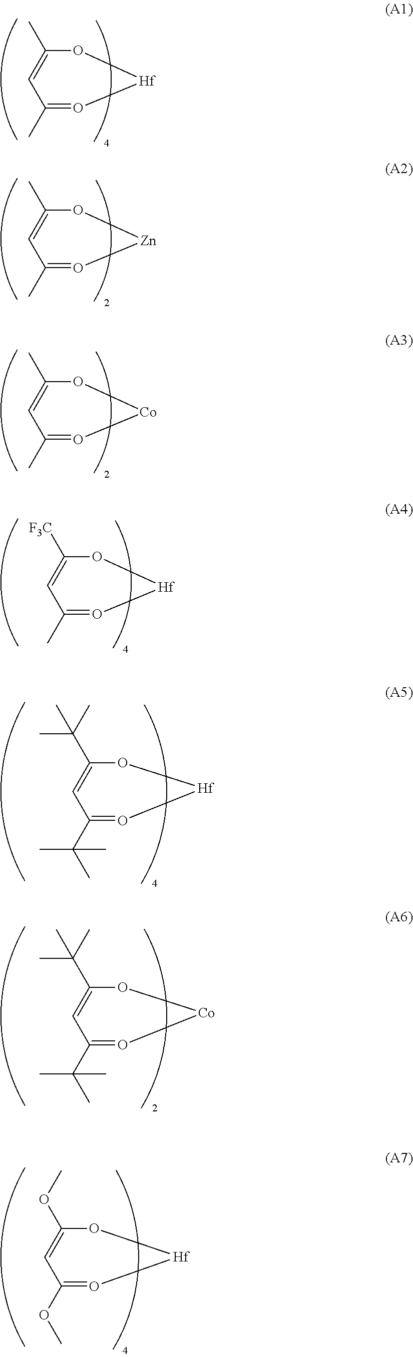

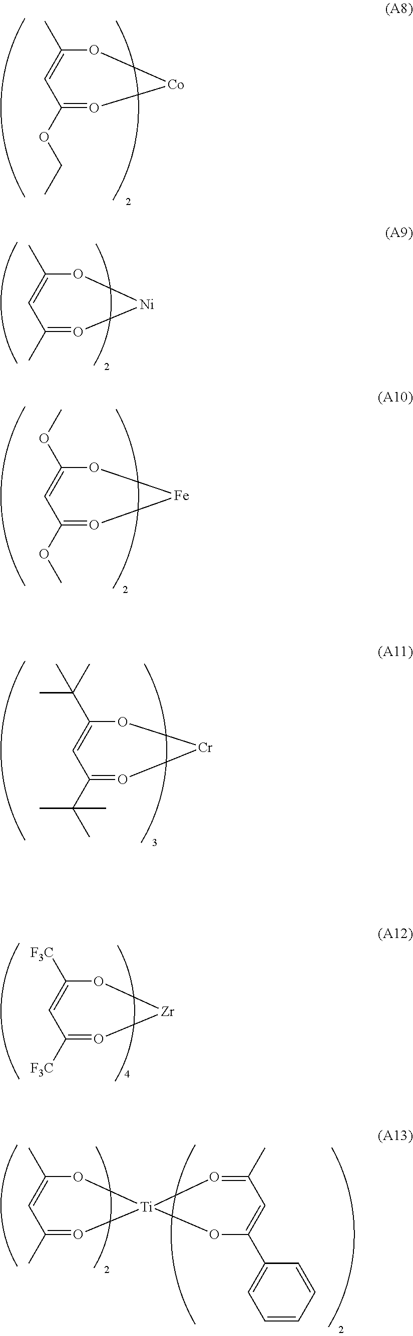

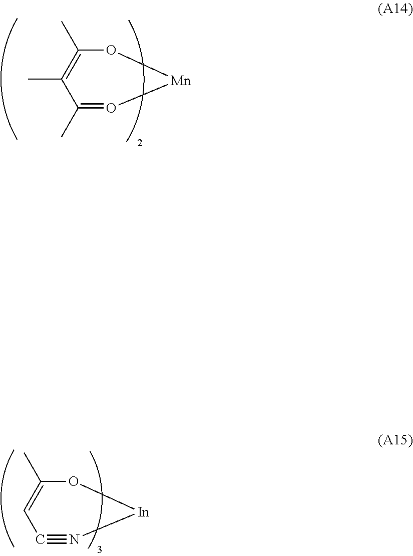

Of these, the complex (A) is preferably one of the complexes (A1) to (A8).

The complex (A) is preferably a complex in which solubility in a developer solution is decreased upon irradiation with an ultraviolet ray, a far ultraviolet ray, an extreme ultraviolet ray, or an electron beam. When the complex (A) has such a property, a change in solubility in the developer solution from before to after the irradiation with the radioactive ray can be increased, and accordingly, the resolution and the sensitivity can be further improved. Moreover, using the complex (A) having such a property enables the radiation-sensitive composition (X) to have a negative tone.

### Synthesis Procedure of (A) Complex

The complex (A) can be synthesized by, for example, adding the compound (2) which gives L in the above formula (1) to a complex in which an anionic ligand such as an alkoxide ion, a halide ion, a carboxylic acid ion, or a dialkylamide ion is coordinated to the metal atom represented by M in the above formula (1), and carrying out ligand substitution. Furthermore, a commercially available product can be used as the complex (A).

The lower limit of a percentage content of the complex (A) with respect to total components other than the organic solvent (B) in the radiation-sensitive composition (X) is preferably 30% by mass, more preferably 50% by mass, still more preferably 70% by mass, and particularly preferably 90% by mass. The upper limit of the percentage content is, for example, 100% by mass, and is preferably 99% by mass and more preferably 97% by mass. When the percentage content of the complex (A) falls within the above range, the resolution and the sensitivity of the radiation-sensitive composition (X) can be further improved. The radiation-sensitive composition (X) may contain one, or two or more types of the complex (A).

(B) Organic Solvent

The organic solvent (B) is not particularly limited as long as it is an organic solvent capable of dissolving or dispersing at least the complex (A) and the other component(s), such as the acid generating agent (C), etc., which is/are contained as necessary. Either one type, or two or more types of the organic solvent (B) may be used.

The organic solvent (B) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as isopropyl alcohol, 4-methyl-2-pentanol, and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as 1-ethoxy-2-propanol; and the like.

Examples of the ether solvent include:

dialkyl ethers solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl-n-propyl ketone, methyl-n-butyl ketone, diethyl ketone, methyl-iso-butyl ketone, 2-heptanone, ethyl-n-butyl ketone, methyl-n-hexyl ketone, di-iso-butyl ketone, and trimethylnonanone;

cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate (PGMEA);

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-heptane and n-hexane;

aromatic hydrocarbon solvents having 6 to 16 carbon atoms such as toluene and xylene; and the like.

Of these, the organic solvent (B) is preferably the alcohol solvent, more preferably the polyhydric alcohol partial ether solvent, and still more preferably 1-ethoxy-2-propanol.

(C) Acid Generating Agent

The acid generating agent (C) is a component which generates an acid by irradiation with a radioactive ray. A change in the solubility of the complex (A) of the radiation-sensitive composition (X) in a developer solution and the like can be further promoted by an action of the acid generated from the acid generating agent (C), and as a result, the resolution and the sensitivity can be further improved.

The acid generating agent (C) is exemplified by an onium salt compound, an N-sulfonyloxyimide compound, a halogen-containing compound, a diazoketone compound, and the like.

Examples of the onium salt compound include a sulfonium salt, a tetrahydrothiophenium salt, an iodonium salt, a phosphonium salt, a diazonium salt, a pyridinium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium nonafluoro-n-butanesulfonate, 4-methanesulfonylphenyldiphenylsulfonium nonafluoro-n-butanesulfonate, triphenylsulfonium 1,1,2,2-tetrafluoro-6-(1-adamantanecarbonyloxy)-hexane-1 -sulfonate, triphenylsulfonium 2-(1-adamantyl)-1,1-difluoroethanesulfonate, triphenylsulfonium 2-(adamantane-1-ylcarbonyloxy)-1,1,3,3,3-pentafluoropropane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate, 1-(6-n-butoxynaphthalen-2-yl)tetrahydrothiophenium nonafluoro-n-butanesulfonate, 1-(3,5-dimethyl-4-hydroxyphenyl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium nonafluoro-n-butanesulfonate, and the like.

Examples of the N-sulfonyloxyimide compound include N-(trifluoromethylsulfonyloxy)-1,8-naphthalimide, N-(trifluoromethylsulfonyloxy)bicyclo[2.2.1]hept-5-ene-2,3-dicarboxyimide, N-(nonafluoro-n-butylsulfonyloxy)bicyclo[2.2.1]hept-5-ene-2,3-dicarboxyimide, N-(perfluoro-n-octylsulfonyloxy)-1,8-naphthalimide, N-(perfluoro-n-octylsulfonyloxy)bicyclo[2.2.1]hept-5-ene-2,3 -dicarboxyimide, N-(2-bicyclo[2.2.1]hept-2-yl-1,1,2,2-tetrafluoroethylsulfonyloxy)bicyclo[2.2.1]hept-5-ene-2,3-dicarboxyimide, N-(2-(3-tetracyclo[4.4.0.1^{2,5}.1^{7,10}]dodecanyl)-1,1-difluoroethylsulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, the acid generating agent (C) is preferably the onium salt compound or the N-sulfonyloxyimide compound, more preferably the sulfonium salt or the N-sulfonyloxyimide compound, still more preferably the N-sulfonyloxyimide compound, and particularly preferably N-(trifluoromethylsulfonyloxy)-1,8-naphthalimide.

In the case in which the radiation-sensitive composition (X) contains the acid generating agent (C), the lower limit of a content of the acid generating agent (C) with respect to 100 parts by mass of the complex (A) is preferably 0.1 parts by mass, more preferably 1 part by mass, and still more preferably 3 parts by mass. The upper limit of the content is preferably 40 parts by mass, more preferably 20 parts by mass, and still more preferably 10 parts by mass.

When the content of the acid generating agent (C) falls within the above range, the resolution and the sensitivity of the radiation-sensitive composition (X) can be further improved. Either one type, or two or more types of the acid generating agent (C) may be used.

Other Component(s)

The other component(s) is/are exemplified by a radiation-sensitive radical generating agent, an acid diffusion control agent, a surfactant, and the like. The radiation-sensitive composition (X) may contain one, or two or more types of the other component(s).

Radiation-Sensitive Radical Generating Agent

The radiation-sensitive radical generating agent is a component which generates a radical by irradiation with a radioactive ray. A well-known compound may be used as the radiation-sensitive radical generating agent.

In the case in which the radiation-sensitive composition (X) contains the radiation-sensitive radical generating agent, a content of the radiation-sensitive radical generating agent may be variously set within a range not leading to impairment of the effects of the present invention.

Acid Diffusion Control Agent

The acid diffusion control agent is able to control a diffusion phenomenon, in the film, of the acid generated from the acid generating agent (C) and the like upon exposure, thereby serving to inhibit unwanted chemical reactions in a non-exposed region. Furthermore, storage stability and the resolution of the radiation-sensitive composition (X) are each further improved. Moreover, changes in line width of the pattern caused by variation of post-exposure time delay from the exposure until a development treatment can be suppressed, thereby enabling the radiation-sensitive composition (X) to be obtained having superior process stability.

The acid diffusion control agent is exemplified by a nitrogen atom-containing compound, a photodegradable base that generates a weak acid by irradiation with a radioactive ray, and the like.

Examples of the nitrogen atom-containing compound include:

amine compounds, for example,

monoamines, e.g., monoalkylamines such as n-hexylamine, dialkylamines such as di-n-butylamine, trialkylamines such as triethylamine, and aromatic amines such as aniline,

diamines such as ethylenediamine and N,N,N′,N′ -tetramethylethylenediamine,

polyamines such as polyethyleneimine and polyallylamine, and

polymers of dimethylaminoethylacrylamide and the like;

amide group-containing compounds such as formamide and N-methylformamide;

urea compounds such as urea and methylurea;

pyridine compounds such as pyridine and 2-methylpyridine; morpholine compounds such as N-propylmorpholine and N-(undecylcarbonyloxyethyl)morpholine; nitrogen-containing heterocyclic compounds such as pyrazine and pyrazole;

nitrogen-containing heterocyclic compounds having an acid-labile group, such as N-t-butoxycarbonylpiperidine and N-t-butoxycarbonylimidazole; and the like.

The photolabile base is exemplified by an onium salt compound that loses acid diffusion controllability through degradation upon exposure, and the like. Exemplary onium salt compounds include triphenylsulfonium salts, diphenyliodonium salts, and the like.

Examples of the photolabile base include triphenylsulfonium salicylate, triphenylsulfonium 10-camphorsulfonate, and the like.

In the case in which the radiation-sensitive composition (X) contains the acid diffusion control agent, the lower limit of a percentage content of the acid diffusion control agent with respect to total components other than the organic solvent (B) in the radiation-sensitive composition (X) is preferably 0.1% by mass, more preferably 0.3% by mass, and still more preferably 1% by mass. The upper limit of the percentage content is preferably 20% by mass, more preferably 10% by mass, and still more preferably 5% by mass.

In the case in which the radiation-sensitive composition (X) contains the acid diffusion control agent, the lower limit of a content of the acid diffusion control agent with respect to 100 parts by mass of the complex (A) is preferably 0.1 parts by mass, more preferably 0.3 parts by mass, and still more preferably 1 part by mass. The upper limit of the content is preferably 20 parts by mass, more preferably 10 parts by mass, and still more preferably 5 parts by mass.

When the content of the acid diffusion control agent falls within the above ranges, the resolution and the sensitivity of the radiation-sensitive composition (X) can be further improved.

Surfactant

The surfactant is a component that exhibits an effect of improving coating properties, striation, and the like. Examples of the surfactant include nonionic surfactants such as polyoxyethylene lauryl ether, polyoxyethylene stearyl ether, polyoxyethylene oleyl ether, polyoxyethylene n-octyl phenyl ether, polyoxyethylene n-nonyl phenyl ether, polyethylene glycol dilaurate, and polyethylene glycol distearate; and the like. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from available from Tohkem Products Corporation (Mitsubishi Materials Electronic Chemicals Co., Ltd.)), Megaface F171 and Megaface F173 (each available from DIC Corporation), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.), and the like.

### Preparation Procedure of Radiation-Sensitive Composition

The radiation-sensitive composition (X) may be prepared by, for example, mixing the complex (A) and the organic solvent (B), as well as the acid generating agent (C), the other component(s), and the like, which are added as needed, in a predetermined ratio, and preferably filtering a thus resulting mixture through a filter having a pore size of about 0.2 μm. The lower limit of a solid content concentration of the radiation-sensitive composition (X) is preferably 0.1% by mass, more preferably 0.5% by mass, still more preferably 1% by mass, and particularly preferably 2% by mass. On the other hand, the upper limit of the solid content concentration is preferably 50% by mass, more preferably 30% by mass, still more preferably 10% by mass, and particularly preferably 5% by mass. The term “solid content concentration” as referred to herein means a concentration on a mass basis, being a sum of all components other than the organic solvent (B) in the radiation-sensitive composition

Next, the applying step will be described. Specifically, the film is formed by applying the radiation-sensitive composition (X) to form a coating film such that the resulting film has a desired thickness, followed by, as needed, prebaking (PB) to volatilize the organic solvent and the like in the coating film. A procedure for applying the radiation-sensitive composition (X) on a substrate is not particularly limited, and an appropriate application procedure such as spin-coating, cast coating, roller coating, etc. may be employed. Examples of the substrate include a silicon wafer, a wafer coated with aluminum, and the like. It is to be noted that an organic or inorganic antireflective film may also be formed on the substrate in order to maximize potential of the radiation-sensitive composition.

The lower limit of an average thickness of the film formed in this step is preferably 1 nm, more preferably 5 nm, still more preferably 10 nm, and particularly preferably 20 nm. On the other hand, the upper limit of the average thickness is preferably 1,000 nm, more preferably 200 nm, still more preferably 100 nm, and particularly preferably 70 nm.

The lower limit of a PB temperature is typically 30° C., preferably 35° C., and more preferably 40° C. The upper limit of the PB temperature is typically 140° C., and preferably 100° C. The lower limit of a PB time period is typically 5 sec, and preferably 10 sec. The upper limit of the PB time period is typically 24 hrs, preferably 1 hour, more preferably 600 sec, and still more preferably 300 sec.

In this step, in order to preclude influences from basic impurities and the like included in an environmental atmosphere, for example, a protective film may be provided on the film formed. Furthermore, in a case of conducting liquid immersion lithography in the exposing step, as described later, a protective film for liquid immersion may be provided on the film formed in order to prevent direct contact between a liquid immersion medium and the film.

Exposing Step

In this step, the film formed by the applying step is exposed to an ultraviolet ray, a far ultraviolet ray, an extreme ultraviolet ray, or an electron beam. Specifically, the film is irradiated with a radioactive ray through, for example, a mask having a predetermined pattern. In this step, the irradiation with the radioactive ray may be conducted through a liquid immersion medium such as water or the like, i.e., liquid immersion lithography may be adopted. The radioactive ray is preferably a far ultraviolet ray, an extreme ultraviolet ray, or an electron beam, more preferably an ArF excimer laser beam, a KrF excimer laser beam, an extreme ultraviolet ray, or an electron beam, and still more preferably an extreme ultraviolet ray or an electron beam.

Developing Step

In this step, a developer solution is used to develop the film following the exposing step. By this step, a predetermined pattern is formed. The developer solution is exemplified by an alkaline aqueous solution, an organic solvent-containing liquid, and the like. In other words, a development procedure may be development with an alkali or development with an organic solvent, and is preferably the development with an organic solvent.

Examples of the alkaline aqueous solution include alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, and 1,5-diazabicyclo-[4.3.0]-5-nonene, and the like.

The lower limit of a percentage content of the alkaline compound in the alkaline aqueous solution is preferably 0.1% by mass, more preferably 0.5% by mass, and still more preferably 1% by mass. The upper limit of the percentage content is preferably 20% by mass, more preferably 10% by mass, and still more preferably 5% by mass.

The alkaline aqueous solution is preferably an aqueous TMAH solution, and more preferably a 2.38% by mass aqueous TMAH solution.

Examples of the organic solvent in the organic solvent-containing liquid include organic solvents similar to those exemplified as the organic solvent (B) in the radiation-sensitive composition (X), and the like. Of these, the organic solvent is preferably a solvent selected from the group consisting of the alcohol solvent, the hydrocarbon solvent, and the ester solvent, and more preferably a solvent selected from the group consisting of isopropyl alcohol, 4-methyl-2-pentanol, toluene, and butyl acetate.

The lower limit of a percentage content of the organic solvent in the organic solvent-containing liquid is preferably 80% by mass, more preferably 90% by mass, still more preferably 95% by mass, and particularly preferably 99% by mass. When the percentage content of the organic solvent falls within the above range, a contrast of rates of dissolution in the developer solution between a light-exposed region and a light-unexposed region can be further improved. It is to be noted that that a component of the organic solvent-containing liquid other than the organic solvent may be, for example, water, silicone oil, or the like.

A surfactant may be added to the developer solution in an appropriate amount, as necessary. As the surfactant, for example, an ionic or nonionic fluorochemical surfactant, a silicone-based surfactant, or the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate and allowed to stand still for a given time period to conduct a development; a spraying procedure in which the developer solution is sprayed onto the surface of the substrate; a dynamic dispensing procedure in which the developer solution is continuously applied onto the substrate, which is rotated at a constant speed, while scanning with a developer solution-application nozzle at a constant speed; and the like.

It is preferred that, following the development, the substrate is rinsed by using a rinse agent such as water, alcohol, or the like, and then dried. A procedure for the rinsing is exemplified by: a spin-coating procedure in which the rinse agent is continuously applied onto the substrate, which is rotated at a constant speed; a dipping procedure in which the substrate is immersed for a given time period in the rinse agent charged in a container; a spraying procedure in which the rinse agent is sprayed onto the surface of the substrate; and the like.

### EXAMPLES

Hereinafter, the present invention is explained in detail by way of Examples, but the present invention is not in any way limited to these Examples.

The complex (A) used in preparing each radiation-sensitive composition is shown below. Commercially available products were used for complexes (A-1) to (A4), and complexes (A-5) to (A-8) were synthesized by operations shown in the following Synthesis Examples 2 to 5.

(A) Complex

A-1: hafnium(IV) tetraacetylacetonato (a compound represented by the following formula (A-1))

A-2: zinc diacetylacetonato (a compound represented by the following formula (A-2))

A-3: cobalt(II) diacetylacetonato (a compound represented by the following formula (A-3))

A-4: hafnium(IV) tetratrifluoroacetylacetonato (a compound represented by the following formula (A-4))

A-5: hafnium(IV) tetra 2,2,6,6-tetramethyl-3,5-heptanedionato (a compound represented by the following formula (A-5))

A-6: cobalt(II) di 2,2,6,6-tetramethyl-3,5-heptanedionato (a compound represented by the following formula (A-6))

A-7: hafnium(IV) tetradimethylmalonato (a compound represented by the following formula (A-7))

A-8: cobalt(II) diethylacetoacetonato (a compound represented by the following formula (A-8))

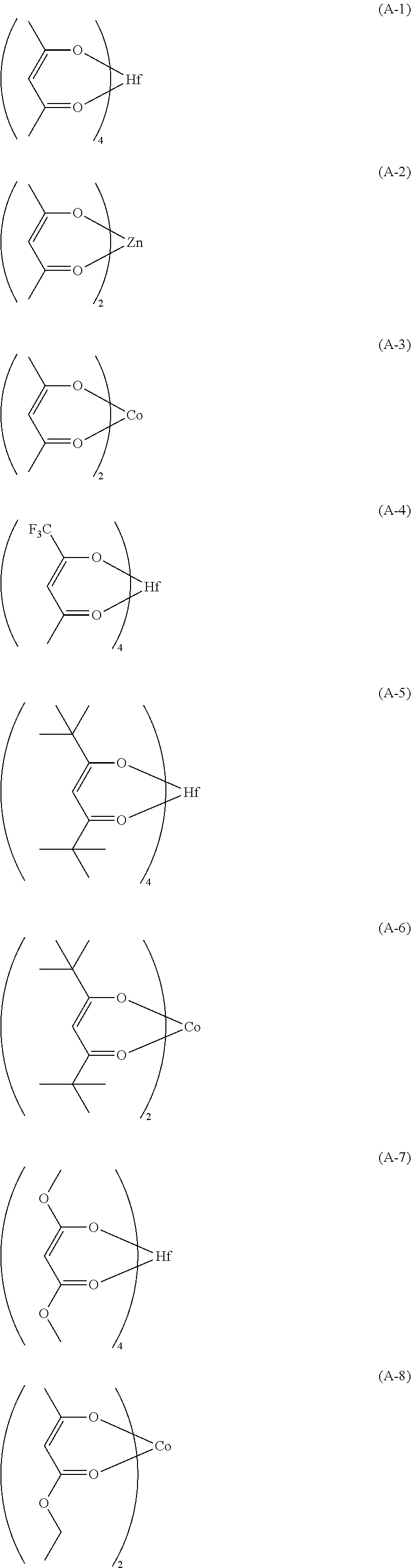

### Synthesis Example 1

2.7 g of zirconium(IV) tetraisopropoxide was dissolved in 9 g of methacrylic acid, and a solution thus obtained was heated at 65° C. for 2 hrs. A reaction solution thus obtained was washed with hexane, and then drying gave particles (Z-1) containing mainly a metal atom and a ligand derived from an organic acid.

### Synthesis Example 2

11.8 g of hafnium(IV) tetraisopropoxide isopropanol was dissolved in 70 mL of hexane. To a solution thus obtained was added 20.8 mL of 2,2,6,6-tetramethyl-3,5-heptanedione, and a resulting solution was heated for 1 hour under heating reflux conditions. After a solvent was distilled off by concentration under reduced pressure and remaining residue was dissolved in 10 mL of heated hexane, cooling gave the complex (A-5).

### Synthesis Example 3

2.6 g of cobalt(II) chloride was dissolved in 15 mL of water, and to a resulting solution was added 8.2 mL of 2,2,6,6-tetramethyl-3,5-heptanedione. To a mixture thus obtained was added a solution constituted from 5.2 g of ethyl acetoacetate and 10 mL of methanol. Moreover, an aqueous solution of sodium hydroxide prepared from 0.8 g of sodium hydroxide and 15 mL of water was added thereto, and a resulting solution was stirred at room temperature for 3 hrs. Filtering to obtain precipitate and washing the same with 50 mL of water gave the complex (A-6).

### Synthesis Example 4

40.5 g of hafnium(IV) tetra-diethylamide was dissolved in 20 mL of diethyl ether, and then a solution constituted from 0.5 g of dimethyl malonate and 20 mL of diethyl ether was added dropwise thereto over 1 hour. A resulting solution was stirred at room temperature for 24 hrs, and then distilling a solvent off by concentration under reduced pressure gave the complex (A-7).

### Synthesis Example 5

5.0 g of cobalt(II) acetate tetrahydrate was dissolved in 15 mL of water, and thereto was then added a solution constituted from 5.2 g of ethyl acetoacetate and 10 mL of methanol. To a mixture thus obtained was added a solution constituted from 4.0 g of triethylamine and 10 mL of methanol, and a resulting solution was stirred for 3 hrs at room temperature. Filtering to obtain precipitate and washing the same with 50 mL of cooled methanol gave the complex (A-8).

### Preparation of Radiation-Sensitive Composition

The organic solvent (B) and the acid generating agent (C) used in preparing each radiation-sensitive composition are shown below.

(B) Organic Solvent

B-1: propylene glycol monomethyl ether acetate (a compound represented by the following formula (B-1))

B-2: 1-ethoxy-2-propanol (a compound represented by the following formula (B-2))

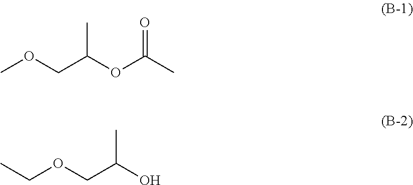

(C) Acid Generating Agent

C-1: N-(trifluoromethylsulfonyloxy)-1,8-naphthalimide (a compound represented by the following formula (C-1))

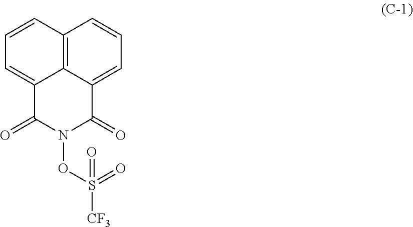 [SMILES: O=C1c2cccc3cccc(c23)C(=O)N1OS(=O)(=O)C(F)(F)F]

### Comparative Example 1

A mixed liquid having a solid content concentration of 3% by mass was provided by: mixing 100 parts by mass of the particles (Z-1), corresponding to the complex (A); (B-1) as the organic solvent (B); and 10 parts by mass of (C-1) as the acid generating agent (C). The mixed liquid thus obtained was filtered through a membrane filter having a pore size of 0.20 μm to prepare a radiation-sensitive composition (R-1).

### Examples 1 to 8

Each of radiation-sensitive compositions (R-2) to (R-9) was prepared such that the solid content concentration was 3% by mass, by a similar operation to that of Comparative Example 1, except that each component of the type and in the amount shown in Table 1 below was used.

TABLE 1

| | | | | | (C) Acid generating | |
|---|---|---|---|---|---|---|
| | | (A) Complex | | | agent | |
| | Radiation-sensitive | | content (parts by | (B) Organic | | content (parts by |
| | composition | type | mass) | solvent | type | mass) |
| Comparative | R-1 | Z-1 | 100 | B-1 | C-1 | 10 |
| Example 1 | | | | | | |
| Example 1 | R-2 | A-1 | 100 | B-2 | C-1 | 5 |
| Example 2 | R-3 | A-2 | 100 | B-2 | C-1 | 5 |
| Example 3 | R-4 | A-3 | 100 | B-2 | C-1 | 5 |
| Example 4 | R-5 | A-4 | 100 | B-2 | C-1 | 5 |
| Example 5 | R-6 | A-5 | 100 | B-2 | C-1 | 5 |
| Example 6 | R-7 | A-6 | 100 | B-2 | C-1 | 5 |
| Example 7 | R-8 | A-7 | 100 | B-2 | C-1 | 5 |
| Example 8 | R-9 | A-8 | 100 | B-2 | C-1 | 5 |

### Pattern Formation

### Comparative Example 1

The radiation-sensitive composition (R-1) prepared in Comparative Example 1 was spin-coated onto a silicon wafer using a simplified spin coater to form a film having an average thickness of 50 nm. Next, the film was exposed to an electron beam using an electron beam writer (“JBX-9500FS,” available from JEOL, Ltd.) to permit patterning. Following the exposure to the electron beam, the film was developed with toluene, and then dried to form a negative-tone pattern.

### Examples 1 to 8

Patterning using each radiation-sensitive composition was conducted by a similar operation to that of Comparative Example 1, except that each radiation-sensitive composition shown in Table 2 below was used.

### Evaluations

Using the patterns formed as described above, each of the radiation-sensitive compositions was evaluated on the resolution and the sensitivity by the following methods. The results of the evaluations are shown together in Table 2 below.

Resolution

Line and space patterns (1L 1S) were produced to have various line widths, then a half-pitch of the pattern in which a total of the line widths and the space widths was the smallest among the line and space patterns having the line width of 1:1 being maintained was defined as a limiting resolution (nm), and the limiting resolution was employed as a marker for the resolution. A smaller limiting resolution value indicates superior resolution.

Sensitivity

An exposure dose at which a line-and-space pattern (1L 1S) with a line width of 1:1 was formed was defined as an optimal exposure dose, the pattern being configured with: line parts each having a line width of 100 nm; and space parts formed between adjacent line parts, each being an interval of 100 nm, and the optimal exposure dose was defined as the sensitivity (μC/cm²). A smaller sensitivity value indicates superior sensitivity.

TABLE 2

| | Radiation- | | |
|---|---|---|---|
| | sensitive | Resolution | Sensitivity |
| | composition | (nm) | (μC/cm²) |
| Comparative | R-1 | 70 | 30 |
| Example 1 | | | |
| Example 1 | R-2 | 50 | 50 |
| Example 2 | R-3 | 50 | 55 |
| Example 3 | R-4 | 50 | 55 |
| Example 4 | R-5 | 50 | 45 |
| Example 5 | R-6 | 45 | 40 |
| Example 6 | R-7 | 45 | 45 |
| Example 7 | R-8 | 30 | 30 |
| Example 8 | R-9 | 35 | 40 |

As is clear from the results shown in Table 2 above, the pattern-forming method and the radiation-sensitive compositions of the Examples enable formation of a pattern with high resolution in a highly sensitive manner. It is to be noted that in general, a tendency similar to the case of an exposure to an extreme ultraviolet ray has been known to be exhibited by an exposure to an electron beam. Therefore, it is speculated that according to the pattern-forming method and the radiation-sensitive compositions of the Examples, a pattern having high resolution can be formed with high sensitivity also in the case of the exposure to the extreme ultraviolet ray.

The pattern-forming method and the radiation-sensitive composition of the one embodiment of the present invention enable formation of a pattern with high resolution in a highly sensitive manner. Therefore, these can be suitably used for formation of fine patterns in lithography processes of various types of electronic devices such as semiconductor devices and liquid crystal devices, for which microfabrication is expected to progress further hereafter.

Obviously, numerous modifications and variations of the present invention are possible in light of the above teachings. It is therefore to be understood that within the scope of the appended claims, the invention may be practiced otherwise than as specifically described herein.

What is claimed is:

1. A pattern-forming method comprising:
applying directly or indirectly on a substrate a radiation-sensitive composition comprising a complex and an organic solvent to form a film;
exposing the film to an ultraviolet ray, a far ultraviolet ray, an extreme ultraviolet ray, or an electron beam; and
developing the film exposed,
wherein the complex is represented by formula (1):
[MₘLₙQₚ] (1)
wherein, in the formula (1),
M represents a zinc atom, a cobalt atom, a nickel atom, a hafnium atom, a zirconium atom, a titanium atom, an iron atom, a chromium atom, a manganese atom or an indium atom;
m is a number of atoms represented by M in the complex represented by the formula (1) and is an integer of 1 to 20, wherein in a case in which m is no less than 2, a plurality of Ms are identical or different;
L represents a ligand derived from a compound represented by formula (2):
R¹—CHR³—R² (2)
wherein, in the formula (2),
R¹ and R² each independently represent —C(═O)—R^{A}, —C(═O)—OR^{B}, or —CN, wherein R^{A} and R^{B} each independently represent an aryl group having 6 to 20 carbon atoms or a fluorine atom-substituted or unsubstituted alkyl group having 1 to 20 carbon atoms; and
R³ represents a hydrogen atom or a monovalent hydrocarbon group having 1 to 20 carbon atoms,
n is a number of ligands represented by L in the complex represented by the formula (1) and is an integer of 1 to 80, wherein in a case in which n is no less than 2, a plurality of Ls are identical or different;
Q represents a ligand that does not fall under a definition of L; and
p is a number of ligands represented by Q in the complex represented by the formula (1) and is an integer of 0 to 40, wherein in a case in which p is no less than 2, a plurality of Qs are identical or different.

2. The pattern-forming method according to claim 1, wherein p is 0.

3. The pattern-forming method according to claim 1, wherein M represents a zinc atom, a cobalt atom, or a hafnium atom.

4. The pattern-forming method according to claim 3, wherein M represents a zinc atom.

5. The pattern-forming method according to claim 1, wherein a content of the complex with respect to all components other than the organic solvent in the radiation-sensitive composition is no less than 30% by mass.

6. The pattern-forming method according to claim 1, wherein the radiation-sensitive composition further comprises a radiation-sensitive acid generating agent.

7. A radiation-sensitive composition comprising a complex and an organic solvent,
wherein the complex is represented by formula (1):
[MₘLₙQₚ] (1)
wherein, in the formula (1),
M represents a zinc atom, a cobalt atom, a nickel atom, a hafnium atom, a zirconium atom, a titanium atom, an iron atom, a chromium atom, a manganese atom or an indium atom;
m is a number of atoms represented by M in the complex represented by the formula (1) and is an integer of 1 to 20, wherein in a case in which m is no less than 2, a plurality of Ms are identical or different;
L represents a ligand derived from a compound represented by formula (2):
R¹—CHR³—R² (2)
wherein, in the formula (2),
R¹ and R² each independently represent —C(═O)—R^{A}, —C(═O)—OR^{B}, or —CN, wherein R^{A} and R^{B} each independently represent an aryl group having 6 to 20 carbon atoms or a fluorine atom-substituted or unsubstituted alkyl group having 1 to 20 carbon atoms; and
R³ represents a hydrogen atom or a monovalent hydrocarbon group having 1 to 20 carbon atoms,
n is a number of ligands represented by L in the complex represented by the formula (1) and is an integer of 1 to 80, wherein in a case in which n is no less than 2, a plurality of Ls are identical or different;
Q represents a ligand that does not fall under a definition of L; and
p is a number of ligands represented by Q in the complex represented by the formula (1) and is an integer of 0 to 40, wherein in a case in which p is no less than 2, a plurality of Qs are identical or different.

8. The radiation-sensitive composition according to claim 7, wherein p is 0.

9. The radiation-sensitive composition according to claim 7, wherein M represents a zinc atom, a cobalt atom, or a hafnium atom.

10. The radiation-sensitive composition according to claim 9, wherein M represents a zinc atom.

11. The radiation-sensitive composition according to claim 7, wherein a solubility of the complex in a developer solution is decreased upon irradiation with an ultraviolet ray, a far ultraviolet ray, an extreme ultraviolet ray, or an electron beam.

12. The radiation-sensitive composition according to claim 7, wherein a content of the complex with respect to all components other than the organic solvent is no less than 30% by mass.

13. The radiation-sensitive composition according to claim 7, further comprising a radiation-sensitive acid generating agent.
